(19) United States
(12) Patent Application Publication
(10) Pub. No.: US 2009/0321118 A1
(43) Pub. Date: Dec. 31, 2009

(54) Printed circuit board embedded chip and manufacturing method thereof

(75) Inventors: Woon Chun Kim, Suwon-si (KR); Soon Gyu Yim, Seongnam-si (KR); Joon Seok Kang, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/230,874

(22) Filed: Sep. 5, 2008

(30) Foreign Application Priority Data
Jun. 25, 2008 (KR) 10-2008-0060175

(51) Int. Cl. H05K 1/16; H05K 3/30

(52) U.S. Cl. 174/260; 29/837

(57) ABSTRACT

An electronic component embedded printed circuit board and a manufacturing method thereof. The electronic component embedded printed circuit board includes an insulating layer forming a core layer; an electronic component inserted to project a part thereof on an upper part of the insulating layer; a metallic seed layer formed on the insulating layer including a projected surface of the electronic component; a plating layer formed on the metallic seed layer; circuit patterns electrically connected to pads of the electronic component through via-holes formed on the insulating layer; and a solder resist layer which is formed on the insulating layer and has solder balls attached onto the via-holes electrically connected to the circuit patterns. In the electronic component embedded printed circuit board, a heat radiation characteristic can be maximized and a thickness of the printed circuit board can be minimized. In case that the insulating is made of a thermoplastic resin, the electronic component can be reutilized, thereby saving product cost.

### CROSS-REFERENCE TO RELATED APPLICATIONS

This application claims the benefit of Korean Patent Application No. 10-2008-0060175 filed with the Korea Intellectual Property Office on Jun. 25, 2008, the disclosure of which is incorporated herein by reference.

### BACKGROUND OF THE INVENTION

1. Field of the Invention

The present invention relates to an electronic component embedded printed circuit board and a manufacturing method thereof; and more particularly, to an electronic component embedded printed circuit board in which heat emission efficiency is improved by formation of a pit through adjusting movability of an insulator in the vicinity of a chip of which a part is buried in an insulation layer and the chip of which a part is buried in the insulation layer may be reutilized in case that the insulation layer is an thermoplastic resin based insulation layer, and a manufacturing method thereof.

2. Description of the Related Art

Recently, development of a printed circuit board with various types of electronic elements has attracted public attention as a part of a technology for implementing a multi-functioned and small-sized package.

Up to now, discrete chip resistors or discrete chip capacitors are individually mounted on surfaces of most of printed circuit boards, but recently, a method of manufacturing a printed circuit board with the electronic elements is a technology of substituting chip elements inserted into an inner layer of the board for passive elements such as the conventional chip resistors and discrete chip capacitors by inserting the chip elements such as the discrete chip resistors or the discrete chip capacitor into the inner layer of the board by using new materials and processes.

The board with the electronic elements has high-functionality in addition to merits such as multi-functionality and miniaturization. This is why to provide a measure to enhance a problem in reliability which may occur in wire bonding used in a flip chip or a BGA (Ball Grid Array) or in electrical connection of the electronic elements using a solder ball.

In a conventional method of a printed circuit board with electronic elements such as an IC (Integrated Chip), and the like, as a structure in which the electronic elements are incorporated only on one surface of a core board or one surface of a build-up layer is adopted, the printed circuit board cannot help being configured in an asymmetric structure vulnerable to bending under a thermal stress environment. Accordingly, there is a problem that the board is bent in a direction where the electronic elements are positioned under the thermal stress environment.

There was a limitation that the printed circuit board cannot incorporate electronic elements having a predetermined thickness or more due to this problem. In addition, there is a limitation that lamination materials used in the printed circuit board cannot be manufactured in a predetermined thickness or less due to an electrical insulation property. In this case, a critical thickness for preventing bending is essentially limitative due to a characteristic of a material.

The conventional method of manufacturing the electronic component embedded printed circuit board will now be described in short. First, through-holes having sizes corresponding to sizes of the electronic components to be mounted on a core substrate is formed by providing the core substrate configured by laminating and curing a prepreg on a glass cross.

Next, the electronic components are inserted into the through-holes formed on the core substrate and a filler is charged in the through-holes inserted with the electronic components. The electronic component is fixed to the core substrate by curing the filler for approximately 10 minutes and the electronic component is exposed by grinding the filler and the core substrate with a grinding paper.

Hereinafter, a resin insulation layer is laminated on the electronic component and a via hole is formed through laser processing or drilling processing. A plating layer is formed by performing electroless plating or electrolyte plating on the insulation layer and a resist pattern is formed by etching, thereby manufacturing an electronic component embedded printed circuit board having a predetermined circuit pattern.

Since the electronic component embedded printed circuit board manufactured in such manner is configured in a structure in which the electronic component is buried in a core substrate composed of the insulation layer, heat generated in the electronic components is not smoothly discharged to an outside.

In the conventional printed circuit board, since the electronic components are inserted into the through-holes formed on the core substrate, and is fixed and coupled to the core substrate with the filler, the expensive electronic components are disposed in case that mounting errors of the electronic components occur. Therefore, loss in manufacturing cost is increased.

Since the through-holes for mounting the electronic components on the core substrate should be manufactured in a predetermined size, process loss is increased and working efficiency is lowered.

### SUMMARY OF THE INVENTION

Accordingly, the present invention is contrived to solve the above-described demerits and problems of a conventional electronic component embedded printed circuit board. An object of the present invention is to provide an electronic component embedded printed circuit board which can maximize a heat radiation characteristic of the electronic component by coupling a part of an electronic component to be exposed by using movability of an insulation layer forming a core layer and forming a plating layer surrounding a surface of the exposed electronic component, and reduce a thickness of a printed circuit board by positioning the electronic component in the boundary of the plating layer being in contact with the core layer of the printed circuit board.

Another object of the present invention is to provide a method of manufacturing an electronic component embedded printed circuit board in which an electronic component may be mounted on the board by using movability of an insulation layer through selective heating of the electronic component or the insulation layer without forming an additional cavity on an insulation layer forming a core layer and the electronic component in which a part of the electronic component is buried may be reutilized in case that the insulation layer is made of a thermoplastic resin.

In order to achieve the above-described object, there is provided An electronic component embedded printed circuit board including an insulating layer forming a core layer; an electronic component inserted to project a part thereof on an upper part of the insulating layer; a metallic seed layer formed on the insulating layer including a projected surface of the electronic component; a plating layer formed on the metallic seed layer; circuit patterns electrically connected to pads of the electronic component through via-holes formed on the insulating layer; and a solder resist layer formed on the insulating layer and including solder balls attached onto the via-holes electrically connected to the circuit patterns.

The insulating layer may be made of any one of a thermoplastic resin, a thermosetting resin, and a UV curing resin.

The electronic component is pressed onto the insulating layer at predetermined pressure by being tightly coupled to absorbing apparatuses such as a vacuum press, and the like, whereby the electronic component is inserted into the insulating layer so that a part of the electronic component is exposed on the insulating layer.

At this time, any one of the insulating layer and the electronic component is selectively heated, whereby the insulating layer is granted movability when the electronic component and the insulating are coupled to each other.

A pit may be formed on the insulating layer in the periphery of the electronic component at the time of press-coupling the electronic component. The metallic seed layer covering an exposed surface of the electronic component is formed on the exposed surface of the electronic component and the insulating with the pit at the time of forming the metallic seed layer on the exposed surface of the electronic component and the insulating layer.

In case that the insulating layer is made of the thermoplastic resin, the electronic component is removable by reheating the thermoplastic resin before curing the thermoplastic resin or after curing the thermoplastic resin by cooling, thereby reutilizing the electronic component.

Meanwhile, the metallic seed layer is formed on the surface of the electronic component, which is exposed on the insulating layer. The plating layer having a predetermined thickness is formed on the metallic seed layer.

At this time, the metallic seed layer may be formed by evaporation, electroless plating, or sputtering. The plating layer formed on the metallic seed layer may be formed by electrolytic plating.

In order to achieve another object of the present invention, there is provided a method of manufacturing an electronic component embedded printed circuit board including the steps of: mounting an electronic component on an insulating layer so that a part of the electronic component is exposed on the insulating layer by pressing the electronic component onto the insulating layer; fixing the electronic component by curing the insulating layer; forming a metallic seed layer on a top surface of the insulating layer including an exposed surface of the electronic component; forming a plating layer on the metallic seed layer; forming via-holes at positions on the insulating layer, which correspond to pads of the electronic component and forming circuit patterns electrically conducted with the pads; and forming a solder resist layer having the via-holes electrically connected to the circuit patterns.

After the step of forming the solder resist layer, the method of manufacturing the electronic component embedded printed circuit board further includes the step of forming solder balls in portions where the via-holes electrically connected to the circuit patterns.

In the step of mounting the electronic component on the insulating layer, when any one of the electronic component and the insulating layer is selectively heated, a metallic tape or foil may be attached onto a bottom surface of the insulating layer on which the electronic component is mounted.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of an electronic component embedded printed circuit board in accordance with an embodiment of the present invention;

FIGS. 2 to 8 are cross-sectional views illustrating a manufacturing process of an electronic component embedded printed circuit board in accordance with the present invention; and

FIGS. 9 to 13 are cross-sectional views illustrating a manufacturing process of an electronic component embedded printed circuit board in accordance with another embodiment of the present invention.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

### Electronic Component Embedded Printed Circuit Board

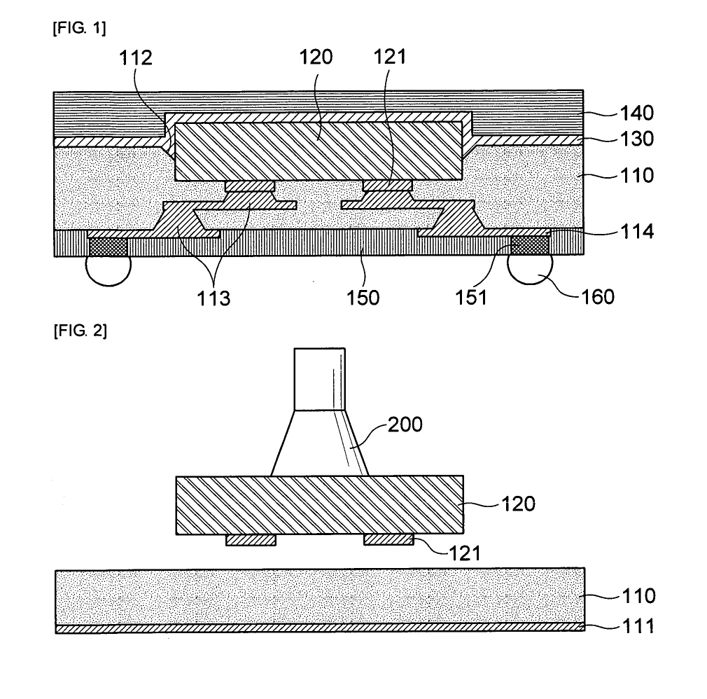

First, FIG. 1 is a cross-sectional view of an electronic component embedded printed circuit board in accordance with an embodiment of the present invention. As shown in the figure, an electronic component embedded printed circuit board 100 includes an insulating layer 110, an electronic component 120 of which a part is buried in the insulating layer 110, a plating layer 140 formed on the insulating layer 110, circuit patterns 114, and a solder resist layer 150 insulated from the circuit pattern 114.

The insulating layer 110 may be made of a thermoplastic resin, a thermosetting resin, a UV curing resin, or a mixed resin of the resins. The part of the electronic component 120 is buried to project on the insulating layer 110.

Pads 121 formed on a bottom surface of the electronic component 120 buried in the insulating layer 110 are electrically connected to the circuit patterns 114 through via-holes 113 formed on the insulating layer 110. A part exposed on the insulating layer is surrounded by a metallic seed layer 130 being in close contact with the metallic plating layer 140.

At this time, the metallic seed layer 130 is formed on an entire top surface of the insulating layer 110 including a surface of the electronic component 120 exposed to the insulating layer 110.

The metallic plating layer 140 is formed on the metallic seed layer 130. The metallic seed layer 130 and the plating layer 140 which are in contact with the exposed surface of the electronic component 120 allow heat generated from the electronic component 120 to be easily emitted to an outside through the metallic seed layer 130 and the plating layer 140.

More specifically, in case of the electronic component 120 of which the part is buried in the insulating layer 110, A part of the electronic component 120 excluding the buried part is fixed to project on a top surface of the insulating layer 110, whereby a top surface and a part of a side surface of the electronic component 120, which are parts projecting on the insulating layer 110 are surrounded by the metallic seed layer 130 and the plating layer 140.

That is, the electronic component 120 is buried on an interface between the insulating layer 110 and the plating layer 140, a contact area of the electronic component 120 with the metallic plating layer 140 may be maximized and discharge efficiency may be maximized when the heat generated from the electronic component 120 is discharged through a contact portion of the metallic seed layer 130 and the plating layer 140 to an outside in contrast to a conventional printed circuit board in which the electronic component is completely buried in the insulating layer.

The electronic component 120 is joined to the insulating layer so that an upper part of the electronic component 120 is exposed by pressing an absorbing device (not shown) in provisional curing of the insulating layer 110. Any one component between the insulating layer 110 and the electronic component 120 is selected and heated at a predetermined temperature, that is, a temperature to provide movability suitable for joining of the electronic component 120 to the insulating layer 110 by pressing in order to maintain the insulating layer 110 in the provisional curing state.

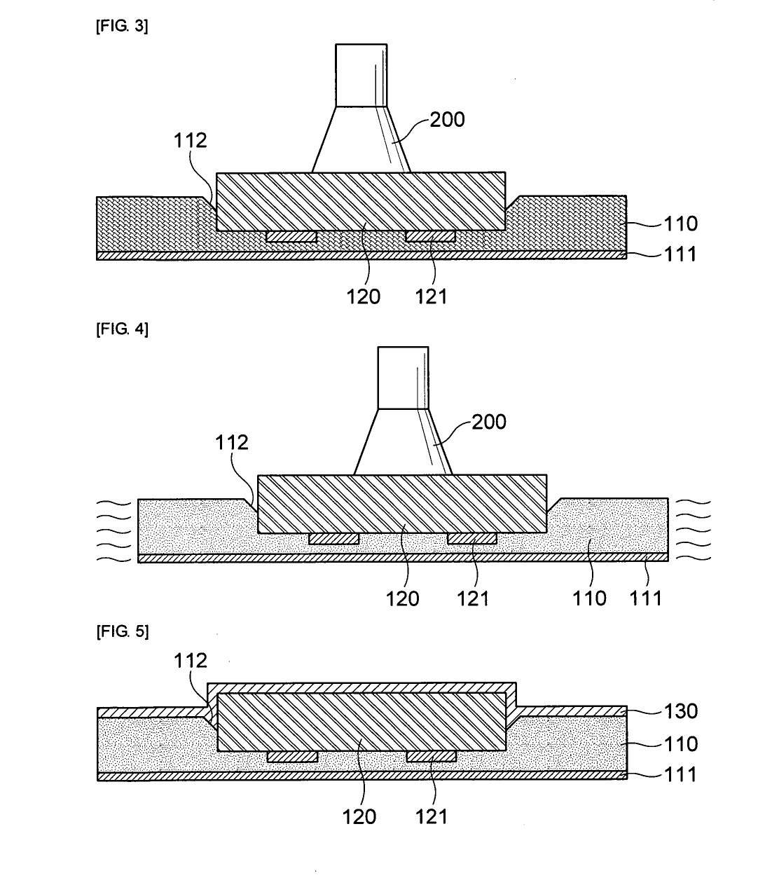

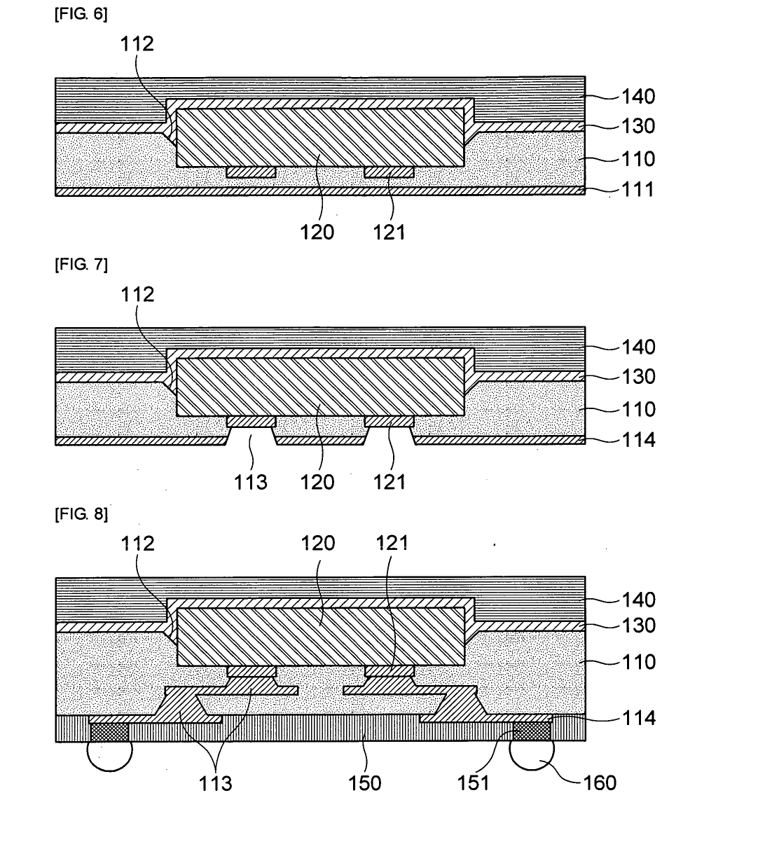

At this time, a metallic tape or foil 111 (see FIGS. 2 to 7) may be attached onto a bottom surface of the insulating layer 110 in order to maintain the insulating layer's own form when the insulating layer 110 has the movability by being heated. The circuit pattern 114 connected to the via-holes 113 may be configured by etching at the time of forming a circuit after forming the plating layer 140 for discharging the heat of the electronic component 120.

Meanwhile, when the electronic component 120 is pressed onto the insulating layer 110 at a predetermined pressure through an additional absorbing device, a pit 112 may be formed on the insulating layer 110 in the periphery of the electronic component 120 by pressing force of the electronic component 120.

The pit 112 formed on the insulating layer 110 may be formed at the time of adjusting heating temperature for adjusting the movability of the insulating layer 110 or at the time of pressing the electronic component 120 by regulating viscosity in resin selection.

When the electronic component 120 is joined to the insulating layer 110, a reason why the pit is formed in the periphery of the electronic component 120 is to improve a heat radiation characteristic of the electronic component 120 by increasing a contact area between the electronic component 120 and the metallic seed layer 130 at most by enabling the metallic seed layer 130 to grow even in an inside of the pit 112 at the time of forming the metallic layer 130 on the surface of the electronic component 120.

As described above, in the printed circuit board 100 having the above-described technical configuration, the insulating layer 110 may adopt various types of insulating resins, for example, a thermosetting resin, a thermoplastic resin, a UV (UltraViolet) curing resin, and the like such as LCP, ABF, PR, PSR, liquid PI, and the like. Among them, in case that the insulating layer 110 is made of the thermoplastic resin, the electronic component 120 may be reutilized.

That is, when the printed circuit board 100 is manufactured through a post process after mounting the electronic component 120 so that the part of the electronic component 120 is exposed on the insulating layer 110 and curing the insulating layer 110, the electronic component 120 is separated from the insulating layer 110 and may be reutilized by reheating the insulating layer 110 made of the thermoplastic resin in case that the post process has a defect.

Accordingly, in case that the insulating layer 110 is made of the thermoplastic resin, the electronic component 120 may be reutilized, thereby the electronic component embedded printed circuit board with the expensive electronic component 120.

Meanwhile, the plating layer 140 for radiating the heat generated in the electronic component 120 to the outside in contact with the insulating layer 110 may be substituted by a conductive paste. That is, the plating layer 140 serves to radiate the heated generated in the electronic component 120 by heat conductive performance. Therefore, the conductive paste is plated directly on the insulating layer 110 serving to radiate the heat and an exposed surface of the electronic component 120 exposed on an upper part of the insulating layer 110, and is cured, thereby configuring a conductive paste layer for heat radiation.

It is preferable that the conductive paste is configured by mixing a paste with comparatively excellent heat conductive efficiency and an adhesive. For example, it is preferable that the conductive paste is composed of a silver (Ag) paste or a copper (Cu) paste.

After this, the solder resist layer 150 with via-holes 151 is formed on one surface of the insulating layer 110 having the circuit patterns 114 formed thereon through a general multilayer printed circuit board manufacturing method. Solder balls 160 are individually in the via-holes 151.

### Method of manufacturing Electronic Component Embedded Printed Circuit Board According to First Embodiment

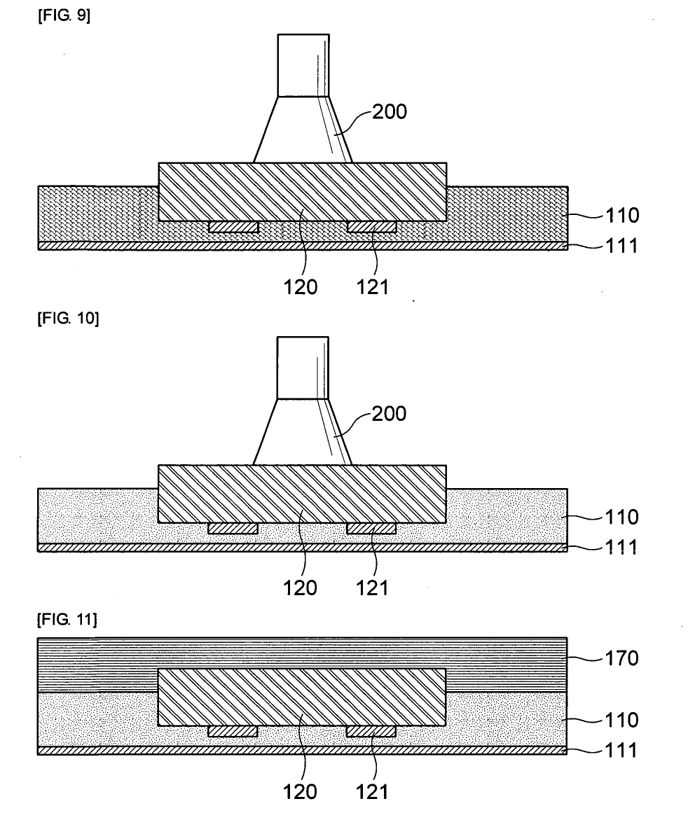

FIGS. 2 to 8 are cross-sectional views illustrating a manufacturing process of an electronic component embedded printed circuit board in accordance with a first embodiment of the present invention.

As shown in the figures, in the method of manufacturing the electronic component embedded printed circuit board in accordance with the embodiment of the present invention, first, an electronic component 120 having a plurality of pads 121 formed on a bottom surface thereof is mounted on an upper part of an insulating layer 110 made of a resin by face-down pressing.

The insulating layer 110 may be made of a thermoplastic resin, a thermosetting resin, a UV curing resin, or a mixed resin of them. Heating any one of the insulating layer 110 and the electronic component 120 at predetermined temperature grants movability to the insulating layer 110 at the time of pressing the electronic component 120 onto the insulating layer 110.

At this time, a metallic tape or foil 111 may be attached onto a bottom surface of the insulating layer 110 in order to maintain the insulating layer's own form when the insulating layer 110 is granted the movablility.

The electronic component 120 inserted into the insulating layer 110 is pressed onto an upper part of the insulating layer 110 with a top surface of the electronic component 120 absorbed by a vacuum pressing member 200. Accordingly, the electronic component 120 is mounted on the insulating layer 110 with only a part of the electronic component 120 buried in the insulating layer 110 by using the only movability without an additional cavity by adjusting pressing force of the pressing member 200.

In addition, when the electronic component 120 is mounted on the insulating layer 110 with a part of a lower part of the electronic component 120 buried in the insulating layer 110, a pit 112 is formed on the insulating layer 110 in the periphery of the electronic component 120.

It is preferable that the insulating layer 110 is made of a resin which can show a viscosity characteristic enough to create the pit 112 at the time of selecting the resin configuring the insulating layer 110.

Next, the electronic component 120 is fixed with the part of the electronic component 120 exposed on the insulating layer 110 by curing the insulating layer 110 mounted with the electronic component 120. At this time, a curing process may depend on a type of the resin configuring the insulating layer 110. In case of the thermoplastic resin, the insulating layer 110 is cured by natural cooling at room temperature while in case of the thermosetting resin or the UV resin, the insulating layer 110 is completed cured by irradiating UV.

Herein, in case that the insulating layer 110 is made of the thermoplastic resin, the insulating layer 110 is also granted the movability by reheating the insulating layer 110 when a fixation position of the electronic component 120 is distorted or a process error occurs after the insulating layer 110 is cured. Accordingly, the electronic component 120 can be reutilized by separating the electronic component 120 from the insulating layer 110.

Next, a metallic seed layer 130 is formed on a top surface of the insulating layer 110 and an exposed surface of the electronic component 120 projecting on the insulating layer 110.

It is preferable that the metallic seed layer 130 is formed in a thin metal film by a process such as sputtering, electroless plating, or the like. The metallic layer 130 is collectively formed even on an inner surface of the pit 112 formed on the insulating layer 110 in the periphery of the electronic component 120.

As described above, a reason why the pit 112 is formed in the insulating layer 110 and the metallic seed layer 130 is formed on up to a side surface of the electronic component 120 within the pit 112 including the inner surface of the pit 112 is to maximize a radiation characteristic by increasing a contact area of the metallic seed layer 130 being in contact with the side surface as well as the exposed top surface of the electronic component 120.

After this, a plating layer 140 is formed on the metallic seed layer 130.

The plating layer 140 is formed on the metallic seed layer 130 in a predetermined thickness by electrolytic plating.

It is preferable that the plating layer 140 is made of a metallic material having high heat conductive efficiency. The plating layer 140 is made mainly of Ag or Cu, whereby heat generated in the electronic component 120 is transmitted to the plating layer 140 through the metallic seed layer 130 and is emitted to an outside.

The plating layer 140 serves to improve emission efficiency of the heat of the electronic component 120 by bringing the plating layer 140 and the surface of the electronic component 120 into direct contact with each other via the metallic seed layer 130.

Next, via-holes 113 are formed at positions on the insulating layer 110 corresponding to pads 121 of the electronic component 120 and circuit patterns 114 electrically conducted with the pads 121 are formed on the insulating layer 110.

After a solder resist layer 150 is formed on one surface of the insulating layer 110 on which the circuit patterns 114 are formed by applying a general multilayer printed circuit board manufacturing method and the via-holes 151 electrically conducted with the circuit patterns 114 are formed on the solder resist layer 150, solder balls 160 for mounting a substrate are individually formed in portions where the via-holes 151 are formed, whereby an electronic component embedded printed circuit board 100 is manufactured.

### Method of Manufacturing Electronic Component Embedded Printed Circuit Board According to Second Embodiment

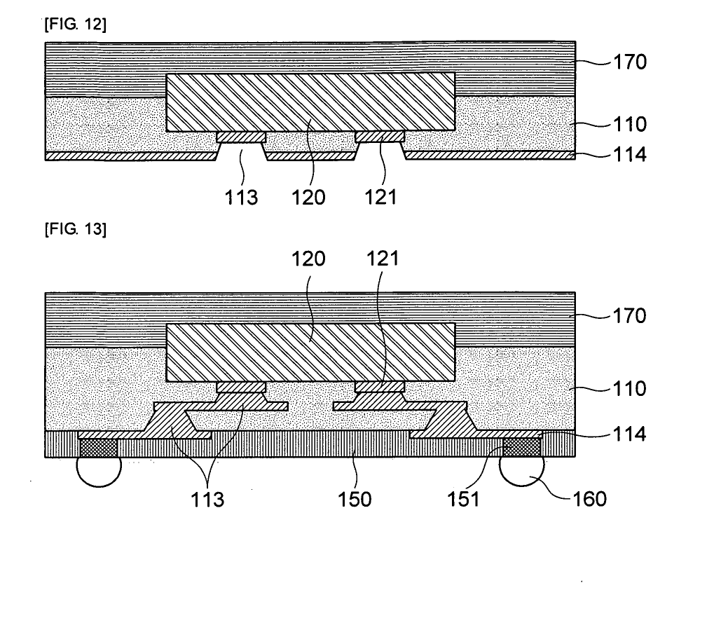

Hereinafter, FIGS. 9 to 13 are cross-sectional views illustrating a manufacturing process of an electronic component embedded printed circuit board in accordance with another embodiment of the present invention.

In detailed description of the electronic component embedded printed circuit board in accordance with this embodiment of the present invention, duplicated description is suppressed with respect to the same manufacturing process and constituent members as the first embodiment as possible, and like reference numerals refer to like elements throughout.

As shown in the figures, in an electronic component embedded printed circuit board 100 in accordance with the embodiment of the present invention, first, an electronic component 120 having a plurality of pads 121 formed on a bottom surface thereof is mounted on an upper part of an insulating layer 110 with an upper part of the electronic component 120 projecting on the insulating layer 110 by using a vacuum pressing member 200.

At this time, a metallic tape or foil 111 may be attached onto a bottom surface of the insulating layer 110 in order to maintain the insulating layer's own form when the insulating layer 110 is granted movablility.

Next, the electronic component 120 is fixed with a part of the electronic component 120 exposed on the insulating layer 110 by curing the insulating layer 110 mounted with the electronic component 120.

Herein, in case that the insulating layer 110 is made of a thermoplastic resin, the insulating layer 110 is also granted the movability by reheating the insulating layer 110 when a fixation position of the electronic component 120 is distorted or a process error occurs after the insulating layer 110 is cured. Accordingly, the electronic component 120 can be reutilized by separating the electronic component 120 from the insulating layer 110.

Next, after a conductive paste layer 170 is formed on the insulating layer 110 and an exposed surface of the electronic component 120 projecting on the insulating layer 110, the conductive paste layer 170 is cured.

The conductive paste layer 170 is composed of a silver (Ag) paste or a copper (Cu) paste which is a paste having high heat conductive efficiency, whereby heat generated in the electronic component 120 is transmitted to the conductive paste layer 170 and is emitted to an outside.

The conductive paste layer 170 may easily be formed by a squeeze method or a screen printing method. Bringing the insulating layer 110 and the surface of the electronic component 120 into direct contact with each other improves emission efficiency of the heat of the electronic component 120.

When the conductive paste layer 170 is collectively formed on the insulating layer 110 and the surface of the electronic component 120, the conductive paste layer 170 may be formed by a simple process and at low cost in comparison with a process of forming the plating layer 140 of the first embodiment, thereby saving whole manufacturing cost of the printed circuit board.

Next, at positions on the insulating layer 110, which correspond to pads 121 of the electronic component 120, via-holes 113 are formed and then circuit patterns 114 electrically conducted with the pads 121 are formed.

After a solder resist layer 150 is formed on one surface of the insulating layer 110 on which the circuit patterns 114 are formed by applying a general multilayer printed circuit board manufacturing method and the via-holes 151 electrically conducted with the circuit patterns 114 are formed on the solder resist layer 150, solder balls 160 for mounting a substrate are individually formed in portions where the via-holes 151 are formed, whereby an electronic component embedded printed circuit board 100 is manufactured.

As described above, in a chip embedded printed circuit board in accordance with the present invention, as the metallic seed layer and a metallic plating layer covers an entire exposed surface of an electronic component mounted on an insulating layer, there are advantages in that a radiation characteristic of the electronic component can be maximized and a thickness of the printed circuit board can be maximized.

In the present invention, in case that the insulating layer is made of a thermoplastic resin, the electronic component may be reutilized when a process error occurs, thereby saving product cost.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. An electronic component embedded printed circuit board comprising:
an insulating layer forming a core layer;
an electronic component inserted to project a part thereof on an upper part of the insulating layer;
a metallic seed layer formed on the insulating layer including a projected surface of the electronic component;
a plating layer formed on the metallic seed layer;
circuit patterns electrically connected to pads of the electronic component through via-holes formed on the insulating layer; and
a solder resist layer formed on the insulating layer and including solder balls attached onto the via-holes electrically connected to the circuit patterns.

2. The electronic component embedded printed circuit board according to claim 1, wherein when any one the insulating layer and the electronic component is heated at predetermined temperature and the electronic component is mounted on the insulating layer, the insulating layer includes movability.

3. The electronic component embedded printed circuit board according to claim 1, wherein a pit is formed on the insulating layer in the periphery of the electronic component.

4. The electronic component embedded printed circuit board according to claim 3, wherein the pit is formed at the time of pressing the electronic component by adjusting viscosity of the insulating layer.

5. The electronic component embedded printed circuit board according to claim 1, wherein the insulating layer is made of any one of a thermoplastic resin, a thermosetting resin, and a UV curing resin, or a mixed resin of the resins.

6. The electronic component embedded printed circuit board according to claim 5, wherein in case that the insulating layer is made of the thermoplastic resin, the electronic component is separated from the insulating layer by reheating the insulating layer, thereby reutilizing the electronic component.

7. The electronic component embedded printed circuit board according to claim 1, wherein a metallic tape or foil is attached onto a bottom surface of the insulating layer in order to maintain the insulating layer's own form when the insulating layer has movability by being heated.

8. The electronic component embedded printed circuit board according to claim 1, wherein the metallic seed layer is formed in a predetermined thickness by evaporation, sputtering, or electroless plating.

9. The electronic component embedded printed circuit board according to claim 1, wherein the plating layer is made of a metallic material such as silver (Ag) or copper (Cu).

10. An electronic component embedded printed circuit board comprising:
an insulating layer forming a core layer;
an electronic component inserted into the insulating layer so that a part of the electronic component projects on an upper part of the insulating layer;
a conductive paste layer formed on the insulating layer including a projected surface of the electronic component;
circuit patterns electrically connected to pads of the electronic component through via-holes formed in the insulating layer; and
a solder resist layer which is formed on the insulating layer and has solder balls attached onto the via-holes electrically connected to the circuit patterns.

11. The electronic component embedded printed circuit board according to claim 10, wherein the conductive paste layer is composed of a silver (Ag) paste or a copper (Cu) paste which is configured by mixing a paste with excellent heat conductive efficiency and an adhesive.

12. The electronic component embedded printed circuit board according to claim 10, wherein a pit is formed on the insulating layer in the periphery of the electronic component.

13. The electronic component embedded printed circuit board according to claim 10, wherein in case that the insulating layer is made of a thermoplastic resin, the electronic component is separated from the insulating layer by reheating the insulating layer, thereby reutilizing the electronic component.

14. A method of manufacturing an electronic component embedded printed circuit board comprising:
mounting an electronic component on an insulating layer so that a part of the electronic component is exposed on the insulating layer by pressing the electronic component onto the insulating layer;
fixing the electronic component by curing the insulating layer;
forming a metallic seed layer on a top surface of the insulating layer including an exposed surface of the electronic component;
forming a plating layer on the metallic seed layer;
forming via-holes at positions on the insulating layer, which correspond to pads of the electronic component and forming circuit patterns electrically conducted with the pads; and
forming a solder resist layer including the via-holes electrically connected to the circuit patterns.

15. The method according to claim 14, further comprising:
forming solder balls in portions where the via-holes electrically connected to the circuit patterns are formed, after the forming the solder resist layer.

16. The method according to claim 14, wherein the insulating layer is made of a thermoplastic resin, a thermosetting resin, a UV curing resin, or a mixed resin of the resins.

17. The method according to claim 14, wherein any one of the insulating layer and the electronic component is selectively heated, whereby the insulating layer is granted movability at the time of pressing the electronic component.

18. The method according to claim 14, wherein in the mounting the electronic component on the insulating layer, a metallic tape or foil is formed on a bottom surface of the insulating layer

19. The method according to claim 14, wherein in the mounting the electronic component on the insulating layer, the electronic component is mounted on the insulating layer a top surface of the electronic component is absorbed by a vacuum member and only a part of the electronic component is buried in the insulating layer by adjusting pressing force.

20. The method according to claim 19, wherein in the mounting the electronic component on the insulating layer, a pit is formed on the insulating layer in the periphery of the electronic component.

21. The method according to claim 14, wherein after the fixing the electronic component by curing the insulating layer, in case that the insulating layer is made of a thermoplastic resin, the electronic component is separated from the insulating layer by reheating the insulating layer, thereby reutilizing the electronic component.

22. The method according to claim 14, wherein the metallic seed layer is composed of a thin metal film by a process such as evaporation, sputtering, or electroless plating.

23. The method according to claim 14, wherein the plating layer is formed in a predetermined thickness by electrolytic plating and is made of a metallic material such as silver (Ag) or copper (Cu).

24. A method of manufacturing an electronic component embedded printed circuit board comprising:
mounting an electronic component on an insulating layer so that a part of the electronic component is exposed on the insulating layer by pressing the electronic component onto the insulating layer;
fixing the electronic component by curing the insulating layer;
forming a conductive paste layer on a top surface of the insulating layer including an exposed surface of the electronic component;
forming via-holes at positions on the insulating layer, which correspond to pads of the electronic component and forming circuit patterns electrically conducted with the pads; and
forming a solder resist layer including the via-holes electrically connected to the circuit patterns.

25. The method according to claim 24, further comprising:
forming solder balls in portions where the via-holes electrically connected to the circuit patterns are formed, after the forming the solder resist layer.

26. The method according to claim 24, wherein the insulating layer is made of a thermoplastic resin, a thermosetting resin, a UV curing resin, or a mixed resin of the resins.

27. The method according to claim 24, wherein in the mounting the electronic component on the insulating layer, a metallic tape or foil is formed on a bottom surface of the insulating layer

28. The method according to claim 24, wherein after the fixing the electronic component by curing the insulating layer, in case that the insulating layer is made of a thermoplastic resin, the electronic component is separated from the insulating layer by reheating the insulating layer, thereby reutilizing the electronic component.

29. The method according to claim 24, wherein the conductive paste is composed of a silver (Ag) paste or a copper (Cu) paste which is configured by mixing a paste with excellent heat conductive efficiency and an adhesive.
